(19) United States
(12) Patent Application Publication
(10) Pub. No.: US 2010/0230695 A1
(43) Pub. Date: Sep. 16, 2010

(54) LED package structure

(75) Inventors: Yu-Bing Lan, Banciao City (TW); Pei-Hsuan Lan, Banciao City (TW)

Correspondence Address: BACON & THOMAS, PLLC, 625 SLATERS LANE, FOURTH FLOOR, ALEXANDRIA, VA, 22314-1176, US

(73) Assignee: Forward Electronics Co., Ltd., Taipei City (TW)

(21) Appl. No.: 12/656,867

(22) Filed: Feb. 18, 2010

(30) Foreign Application Priority Data
Mar. 11, 2009 (TW) 098107803

(51) Int. Cl. H01L 33/52

(52) U.S. Cl. 257/98; 257/E33.061

(57) ABSTRACT

An LED package structure includes an LED chip, an internal transparent colloidal layer, a fluorescent colloidal layer, and an external transparent colloidal layer. The internal transparent colloidal layer is interposed between the LED chip (such as a blue-light LED chip) and the fluorescent colloidal layer (such as a yellow fluorescent colloidal layer), and that the external transparent colloidal layer, in cooperation with the internal transparent colloidal layer, sandwiches and envelops the fluorescent colloidal layer so as to lower the possibility that light emitted from the LED chip may be absorbed by the LED chip itself because the light is scattered backward by particles of the fluorescent powder. This will increase overall lumen output and decrease thermal energy of the LED chip, and will as well provide a more desirable moisture insulation for the fluorescent powder.

### BACKGROUND OF THE INVENTION

1. Field of the Invention

The present invention relates to an LED (light emitting diode) package structure, and more particularly, to an LED package structure having a fluorescent colloidal layer.

2. Description of Related Art

Generally speaking, LEDs have merits on several aspects including long life of use, small size, high vibration resistance, less heat give out, and low power consumption. Therefore; LEDs have been widely applied to household electric appliances and to indicators or light sources of various instruments. In recent years, owing to LEDs' development toward multi-colors and high brightness, LEDs have expanded their range of applications to mobile electronic products as a backlight source for small-size displays. As such, LEDs have become a new lighting source in terms of power saving and environmental protection.

Normally, the backlight source adapted for the flat panel displays of information products mainly adopts white light. Therefore, LEDs, as a backlight source, have to produce white light. In the field, currently, there are several measures for producing white light, namely:

(1) Using a blue-light LED chip, with addition of yellow-green-light fluorescent powder, so as to produce white light—This measure has been widely adopted in the field due to a low cost, though this measure has a notable defect that the white light so produced lacks a red-light portion and has a poor color rendering.

(2) Using a red-light, a blue-light and a green-light LED chips to produce white light, by adjustment to the current passing through the three crystalline chips—This measure is most efficient, though cost for the production is the highest.

(3) Using an UV (ultraviolet) LED chip, and adding red-light, green-light, and blue-light fluorescent powder—This measure has a lower efficiency, let alone UV makes deterioration of epoxy resin easily.

(4) Using a blue-light LED chip, and adding red-light and green-light fluorescent powder. This measure, however, is found a lowest efficiency.

Referring to FIG. 1, a cross-sectional view illustrating part of a conventional LED package structure, this type of LED device requires using fluorescent powder to convert light wavelengths. The conventional LED package structure comprises a carrier such as a reflective bowl-like cup 1, an LED chip 2 such as a blue-light chip, and a fluorescent colloidal layer 3 such as a yellow-light fluorescent powder colloidal layer. The fluorescent colloidal layer 3 contains fluorescent powder particles which are spread over uniformly, where an optical-lens layer 4 covers on the fluorescent colloidal layer 3.

First, the LED chip 2 (blue-light chip) is fixed to the reflective bowl-like cup 1, then through a packaging process, the fluorescent colloidal layer 3 covers directly on the LED chip 2, and when the LED chip 2 emits blue light to the fluorescent powder, the yellow-light fluorescent powder is energized and emits yellow light, and through complement of the blue light and the yellow light, white light is produced.

Nevertheless, during a long-term research on the field, it is found that in the LED package structure, as mentioned above, because the LED chip 2 touches directly the fluorescent colloidal layer 3 and both are too close to each other, the light emitted therefrom scatters at a great portion due to the fluorescent powder particles. In case the scattered light emits back to the LED chip 2, the light will be absorbed and as a whole, light loss occurs.

### SUMMARY OF THE INVENTION

An object of the present invention is to provide an LED package structure for enhancing luminous flux and luminous efficiency of an LED device, and for refraining a fluorescent colloidal layer of the LED device from deterioration due to moisture.

To achieve the above-mentioned object, the LED package structure, according to the present invention, comprises an LED chip, an internal transparent colloidal layer, a fluorescent colloidal layer, and an external transparent colloidal layer. The internal transparent colloidal layer is interposed between the LED chip and the fluorescent colloidal layer, and that the external transparent colloidal layer and the internal transparent colloidal layer sandwich and envelop the fluorescent colloidal layer at upper and down sides thereof.

The internal transparent colloidal layer is made of, for instance, silica gel, epoxy resin, or glass. Further, in case the internal transparent colloidal layer has a refractive index close to that of the LED chip, light can emit out more easily, preferably, the refractive index is 1.33 to 3.0; and that the internal transparent colloidal layer has a transmission efficiency, preferably, of 85% to 100% (per mm).

The LED package structure, according to the present invention, can solve the problems inherent in the conventional art, where the problems include: the fluorescent colloidal layer envelops directly the LED chip and that no appropriate spacing is provided therebetween, so that part of light returns to the LED chip, which has a higher absorptivity, because of scattering of the light. As such, the present invention has merits in reducing thermal energy for the LED chip and in raising overall luminance. On the other hand, through the fluorescent colloidal layer enveloped in the two transparent colloidal layers, fluorescent powder can be prevented from deterioration by moisture so as to assure life of use for LED components.

The LED chip may refer to a blue-light LED chip or a UV LED chip. The fluorescent colloidal layer may refer to a yellow fluorescent colloidal layer, a green fluorescent colloidal layer, or a red fluorescent colloidal layer. The internal and external transparent colloidal layers may be made of silica gel, or of thermoplastic resin including polystyrene, styrene-butadiene-acrylate, poly (methyl methacrylate), polycarbonate, epoxy resin, or glass. The LED chip may be electrically connected with a conductive base.

Preferably, the internal and the external transparent colloidal layers are directed to the same material; and more preferably, both are formed integrally in one piece.

Other objects, advantages, and novel features of the present invention will become more apparent from the following detailed description when taken in conjunction with the accompanying drawings.

### BRIEF DESCRIPTION OF THE DRAWINGS

FIG. 1 is a cross-sectional view illustrating part of a conventional LED package structure;

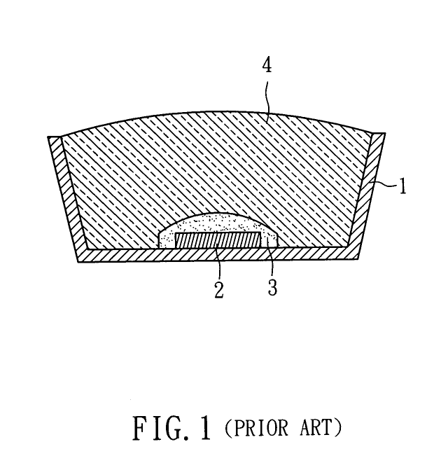

FIG. 2 is a perspective view illustrating an LED package structure according to a first embodiment of the present invention;

FIG. 3 is a cross-sectional view illustrating the LED package structure according to the first embodiment of the present invention; and

FIG. 4 is a cross-sectional view illustrating an LED package structure according to a second embodiment of the present invention.

### DETAILED DESCRIPTION OF THE PREFERRED EMBODIMENTS

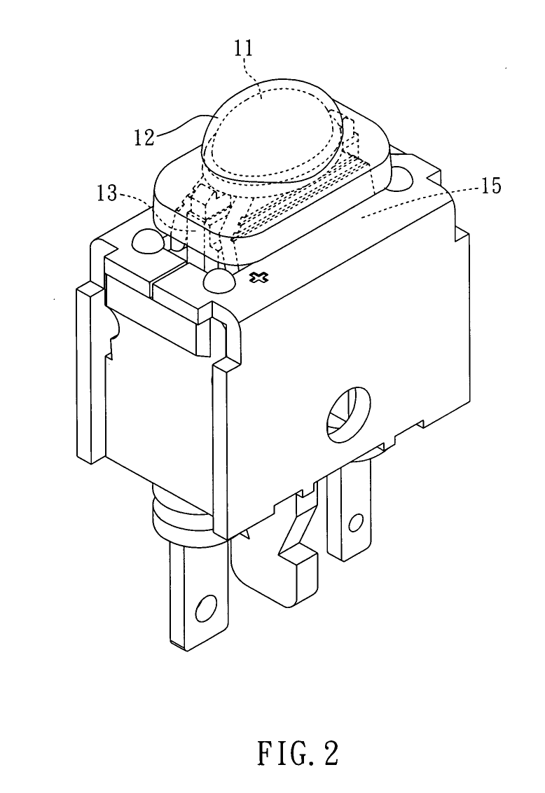

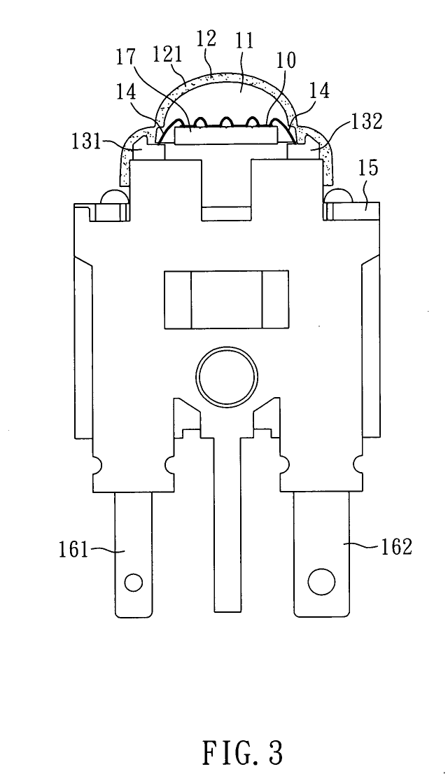

Referring to FIG. 2, a perspective view illustrating an LED package structure according to a first embodiment of the present invention, and to FIG. 3, a cross-sectional view illustrating the LED package structure, the LED package structure comprises an LED chip 10, an internal transparent colloidal layer 11, a fluorescent colloidal layer 12, a conductive base 13, and a heat-sink casing 15. In the present embodiment, the LED chip 10 refers to a blue-light LED chip or an UV LED chip disposed on a chip plane 17. The LED chip 10 is electrically connected with the conductive base 13 through two wires 14. The conductive base 13 consists of a positive-pole frame 131 and a negative-pole frame 132. As shown, the two frames 131,132 extend downward and outside of the LED package structure and turn out to be two leads 161,162. The conductive base 13 and the heat-sink casing 15 are separated from each other by insulation plastics. Heat resulted from operation of the LED chip 10 can be carried out of the LED package structure through the heat-sink casing 15 which is made of metal.

Both the internal transparent colloidal layer 11 and the fluorescent colloidal layer 12 are located above and cover the LED chip 10, where the internal transparent colloidal layer 11 is interposed between the fluorescent colloidal layer 12 and the LED chip 10. Namely, for a relatively simple construction, the internal transparent colloidal layer 11 is directly formed at exterior of and wraps around the LED chip 10; while the fluorescent colloidal layer 12 is thereafter formed and covers the internal transparent colloidal layer 11.

In order to cooperate with the blue-light LED chip 10 so as to emit white light, the fluorescent colloidal layer 12 consists, mostly, of silica gel which contains uniformly-spread yellow fluorescent powder 121. When complying with various LED chips, the fluorescent colloidal layer 12 may be of green fluorescent colloidal layer or red fluorescent colloidal layer. The internal transparent colloidal layer 11 is made of silica gel. In consideration of a better luminous flux, the internal transparent colloidal layer 11 may be material having a refractive index of 1.33 to 3.0 and a transmission efficiency of 85% to 100% (per mm).

The thickness of the internal transparent colloidal layer 11 may vary dependent from the LED chip 10. In the present embodiment, the thickness of the internal transparent colloidal layer 11 lies in 0.5 to 3.5 mm.

An optical-lens layer (not shown) may be provided, additionally, on exterior of the LED structure if necessary, where the material of the optical-lens layer may be silica gel, or thermoplastic resin including polystyrene, styrene-butadiene-acrylate, poly (methyl methacrylate), polycarbonate, epoxy resin, or glass.

Given the above, the LED package structure, according to the present embodiment, is provided with an appropriate spacing between the fluorescent colloidal layer 12 and the LED chip 10 so as to lower the possibility that light may return to the LED chip because of scattering of the light by the fluorescent powder particles. Therefore, a high power LED device would have a high luminous efficiency, high lumen output, and, in the meantime, would lower thermal load of the LED chip 10. Besides, the LED package structure, according to the present embodiment, requires only an additional step in forming an internal transparent colloidal layer 11 prior to forming the fluorescent colloidal layer 12, without substantial changes to the rest of the manufacturing process, as compared with the prior art manufacturing process. Thus, extra cost burden is not too much.

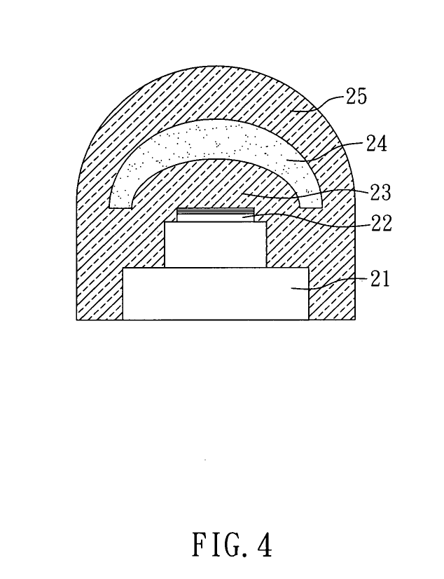

Now referring to FIG. 4, a cross-sectional view illustrating an LED package structure according to a second embodiment of the present invention, the LED package structure comprises, as stacked upward in sequence, a protrusion heat-sink base 21, an LED chip 22, an internal transparent colloidal layer 23, a fluorescent colloidal layer 24, and an external transparent colloidal layer 25. The LED chip 22 is disposed at a protruded portion of the protrusion heat-sink base 21, and that the external transparent colloidal layer 25 acts as a lens layer. In particular, the internal and the external transparent colloidal layers 23,25 are connected with each other so as to envelop the fluorescent colloidal layer 24, such that the fluorescent colloidal layer 24 can be prevented from deterioration by moisture. On the other hand, in case only exterior of the fluorescent colloidal layer 24 was directly covered with and formed as a lens layer, then moisture would permeate into the fluorescent colloidal layer 24 through a border of the lens layer and the protrusion heat-sink base 21. This is because the sealing between materials of the lens layer and the protrusion heat-sink base 21 is poor. As such, to use the two transparent colloidal layers 23,25 to envelop the fluorescent colloidal layer 24 will achieve a desirable sealing effect. Preferably, the internal and the external transparent colloidal layers 23,25 are directed to the same material; and more preferably, both are formed integrally in one piece.

Although the present invention has been explained in relation to its preferred embodiments, it is to be understood that many other possible modifications and variations can be made without departing from the scope of the invention as hereinafter claimed.

What is claimed is:

1. An LED package structure, comprising:
an LED chip;
an internal transparent colloidal layer, being formed on the LED chip;
a fluorescent colloidal layer, being formed on the internal transparent colloidal layer; and
an external transparent colloidal layer, being formed on the fluorescent colloidal layer, and being connected with the internal transparent colloidal layer so as to envelop the fluorescent colloidal layer.

2. The LED package structure as claimed in claim 1, wherein the LED chip is a blue-light LED chip or a UV LED chip.

3. The LED package structure as claimed in claim 1, wherein the fluorescent colloidal layer is a yellow fluorescent colloidal layer, a green fluorescent colloidal layer, or a red fluorescent colloidal layer.

4. The LED package structure as claimed in claim 1, wherein the LED chip is electrically connected with a conductive base.

5. The LED package structure as claimed in claim 1, wherein the internal transparent colloidal layer is made of silica gel, polystyrene, styrene-butadiene-acrylate, poly (methyl methacrylate), polycarbonate, epoxy resin, or glass.

6. The LED package structure as claimed in claim 1, wherein the internal transparent colloidal layer has a refractive index of 1.33 to 3.0 and a transmission efficiency of 85% to 100% (per mm).

7. The LED package structure as claimed in claim 1, wherein the internal and the external transparent colloidal layers are directed to the same material.

8. The LED package structure as claimed in claim 1, wherein the internal and the external transparent colloidal layers are formed integrally in one piece.
